(19) United States
(12) Patent Application Publication
(10) Pub. No.: US 2012/0231583 A1
(43) Pub. Date: Sep. 13, 2012

(54) DIE-BONDING FILM AND USE THEREOF

(76) Inventors: Kenji ONISHI, Osaka (JP); Miki MORITA, Osaka (JP)

(21) Appl. No.: 13/415,689

(22) Filed: Mar. 8, 2012

(30) Foreign Application Priority Data
Mar. 11, 2011 (JP) 2011-054276

(51) Int. Cl. H01L 21/78; C09J 7/02; C09J 137/00

(52) U.S. Cl. 438/114; 524/508; 428/355 AK; 257/E21.599

(57) ABSTRACT

A die-bonding film contains a glycidyl-group-containing acrylic copolymer (a) having a weight-average molecular weight of 500,000 or more and a phenolic resin (b), wherein the weight ratio (x/y) of the content x of the glycidyl-group-containing acrylic copolymer (a) to the content y of the phenolic resin (b) is 5 or more and 30 or less, and the die-bonding film substantially does not contain an epoxy resin having a weight-average molecular weight of 5000 or less. Thus, a die-bonding film having a high reliability is provided by which a sufficient adhering strength and an elastic modulus at a high temperature can be obtained before and after curing; the workability is good; air bubbles (voids) do not stay at the boundary between the die-bonding film and the adherend; and the die-bonding film can withstand a humidity resistance solder reflow test.

### BACKGROUND OF THE INVENTION

1. Field of the Invention

The present invention relates to a thermosetting die-bonding film used when a semiconductor element such as a semiconductor chip is adhered and fixed on an adherend such as a substrate or a lead frame. The present invention also relates to a dicing die-bonding film including the thermosetting die-bonding film and a dicing film layered to each other, and a method for manufacturing a semiconductor device using the dicing die-boding film.

2. Description of the Related Art

Conventionally, silver paste has been used to bond a semiconductor chip to a lead frame or an electrode member in the step of producing a semiconductor device. The treatment for the sticking is conducted by coating a paste-form adhesive on a die pad of a lead frame, or the like, mounting a semiconductor chip on the die pad, and then setting the paste-form adhesive layer.

However, about the paste-form adhesive, the amount of the coated adhesive, the shape of the coated adhesive, and on the like are largely varied in accordance with the viscosity behavior thereof, a deterioration thereof, and on the like. As a result, the thickness of the formed paste-form adhesive layer becomes uneven so that the reliability in strength of bonding a semiconductor chip is poor. In other words, if the amount of the paste-form adhesive coated on an electrode member is insufficient, the adhering strength between the electrode member and a semiconductor chip becomes low so that in a subsequent wire bonding step, the semiconductor chip is peeled. On the other hand, if the amount of the coated paste-form adhesive is too large, this adhesive flows out to stretch over the semiconductor chip so that the characteristic becomes poor. Thus, the yield or the reliability lowers. Such problems about the adhesion treatment become particularly remarkable with an increase in the size of semiconductor chips. It is therefore necessary to control the amount of the coated paste-form adhesive frequently. Thus, the workability or the productivity is deteriorated.

In this coating step of a paste-form adhesive, there is a method for coating the adhesive onto a lead frame or a forming chip by an independent operation. In this method, however, it is difficult to make the paste-form adhesive layer even. Moreover, an especial machine or a long time is required to coat the paste-form adhesive. Thus, a dicing die-bonding film which makes a semiconductor wafer to be bonded and held in a dicing step and further gives an adhesive layer, for bonding a chip, which is necessary for a mounting step is disclosed (see, for example, JP-A-60-57342).

The dicing die-bonding film of this type has a structure in which an adhesive layer (a die-bonding film) is laminated onto a dicing film. The dicing film has a structure in which a pressure-sensitive adhesive layer is laminated onto a support base. This dicing die-bonding film is used as follows. That is, a semiconductor wafer is diced while being held by the die-bonding film, semiconductor chips are peeled off together with the die-bonding film by stretching the support base, and the chips are individually collected. Then, each semiconductor chip is adhered and fixed to an adherend such as a BT substrate or a lead frame with the die-bonding film interposed in between.

### PRIOR ART DOCUMENT

### Patent Document

Patent Document 1 Japanese Patent Application Laid-Open No. 60-57642

In recent years, multiple-stage mounting of semiconductor chips is progressing, and a long period of time tends to be required for a wire bonding step and a step of curing a die-bonding film. When a die-bonding film of a dicing die-bonding film is processed at a high temperature for a long period of time in these steps and a sealing step with a sealing resin is carried out as a later step, a state is sometimes brought about in which air bubbles (voids) stay at a boundary between the die-bonding film and an adherend. When a humidity resistance solder reflow test that is carried out as an evaluation of the reliability of semiconductor-related components using a semiconductor device in which such voids have been generated is carried out, peeling-off is generated at the aforesaid boundary, thereby inviting a circumstance in which the semiconductor device does not have a sufficient reliability. Also, when the die-bonding film is processed at a high temperature for a long period of time, poorness of wire bonding may be generated, or the sealing resin may intrude to the boundary at the time of sealing.

### SUMMARY OF THE INVENTION

The present invention has been made in view of the aforementioned problems, and an object thereof is to provide a die-bonding film having a high reliability by which a sufficient adhering strength and an elastic modulus at a high temperature can be obtained even when, for example, curing is carried out for a short period of time such as about one hour; the workability is good in the wire bonding step and in the sealing step; air bubbles (voids) do not stay at the boundary between the die-bonding film and the adherend even after passing through these steps; further a sufficient shear adhering strength is obtained at a high temperature after the curing; and the die-bonding film can withstand a humidity resistance solder reflow test, as well as a dicing die-bonding film provided with the die-bonding film and a method for manufacturing a semiconductor device.

The inventors of the present application have made studies on a die-bonding film in order to solve the aforementioned problems of the prior art and, as a result thereof, have found out that voids are generated at the boundary between the die-bonding film and the adherend mainly because the low-molecular-weight resin components contained in the die-bonding film react rapidly due to the processing of the die-bonding film at a high temperature, and that the poorness in wire bonding and the sealing resin intrusion at the time of sealing are generated mainly because, when the reaction of the low-molecular-weight resin components proceed, the cohesive strength is not generated and the adhering strength at a high temperature will be insufficient, thereby completing the present invention.

Namely, the die-bonding film of the present invention comprises: a glycidyl-group-containing acrylic copolymer (a) (hereafter sometimes referred to as “copolymer (a)”) having a weight-average molecular weight of 500,000 or more; and a phenolic resin (b), wherein a weight ratio (x/y) of a content x of the copolymer (a) to a content y of the phenolic resin (b) is 5 or more and 30 or less, and the die-bonding film substantially does not contain an epoxy resin (hereafter sometimes referred to as “low-molecular-weight epoxy resin”) having a weight-average molecular weight of 5,000 or less.

With such a construction, according to the die-bonding film, the reaction of the low-molecular-weight resin components is restrained even when a heat treatment at a high temperature for a long period of time is carried out that was not conceived in the past such as the high-temperature treatment for a long period of time in the wire bonding step and in the step of curing the die-bonding film after the die-bonding due to the multiple staging of semiconductor chips, and the generation of air bubbles (voids) at the boundary between the die-bonding film and the adherend can be restrained or made to disappear after the sealing step with a sealing resin which is a step performed later than that. Further, a sufficient shear adhering strength is obtained at a high temperature after the curing, and a high reliability can be ensured in the humidity resistance solder reflow test. When the weight-average molecular weight of the copolymer (a) is less than 500,000, the cohesive strength at the high temperature becomes weak, and a sufficient shear adhering strength may not be obtained. Also, when the aforesaid weight ratio is less than 5, unreacted phenolic resin (b) affects the reliability in the humidity resistance solder reflow test. Also, when the aforesaid weight ratio exceeds 30, the cohesive strength at the high temperature after the curing of the die-bonding film decreases, so that a sufficient shear adhering strength cannot be obtained. Further, when a low-molecular-weight epoxy resin is contained, a rapid reaction occurs at the time of high-temperature treatment, whereby the generation of voids at the boundary or the intrusion of the sealing resin due to the decrease in the adhering strength occurs.

Here, in the present invention, the “epoxy resin having a weight-average molecular weight of 5000 or less” means epoxy resins other than the glycidyl-group-containing acrylic copolymer (a). Also, the fact that the die-bonding film “substantially does not contain” a low-molecular-weight epoxy resin means that the content of the aforesaid low-molecular-weight epoxy resin is sufficiently low to enjoy the effects of the present invention, and the content is preferably 0%. However, a fraction having a weight-average molecular weight of 5000 or less that is inevitably remaining or generated at the time of preparing the copolymer (a) is included within the range of the present invention.

With respect to the glycidyl-group-containing acrylic copolymer (a), it is preferable that an epoxy value thereof is 0.15 e.q./kg or more and 0.65 e.q./kg or less; that a glass transition point thereof is −15° C. or higher and 40° C. or lower; and that a storage elastic modulus thereof at 150° C. is 0.1 MPa or more. When the lower limit of the epoxy value of the copolymer (a) is 0.15 e.q./kg, a sufficient elastic modulus can be obtained at a high temperature after curing. When the upper limit of the epoxy value of the copolymer (a) is 0.65 e.q./kg, the storage property at room temperature can be maintained. Also, when the lower limit of the glass transition point is −15° C., generation of tack at ordinary temperature can be restrained, whereby a good handling property can be maintained. On the other hand, when the upper limit of the glass transition point is 40° C., decrease in the adhering strength of the die-bonding film to a semiconductor wafer such as a silicon wafer can be prevented. In addition, when the storage elastic modulus of the copolymer (a) at 150° C. is 0.1 MPa or more, a sufficient adhering strength can be maintained at the time of wire bonding to the semiconductor chip. As a result of this, shear deformation on the bonding surface between the die-bonding film and the adherend by supersonic vibration or heating can be prevented in performing wire bonding on the semiconductor chip bonded and fixed onto the die-bonding film, whereby the ratio of success of the wire bonding can be improved.

In the die-bonding film, it is preferable that a storage elastic modulus thereof at 50° C. before curing is 10 MPa or less, that a storage elastic modulus thereof at 175° C. is 0.1 MPa or more, and that a storage elastic modulus thereof at 175° C. after curing at 150° C. for one hour is 0.5 MPa or more. When the storage elastic modulus at 50° C. before curing is 10 MPa or less, the wettability to the adherend can be ensured, and the adhering strength can be maintained. When the storage elastic modulus at 175° C. is 0.1 MPa or more, a sufficient adhering strength can be maintained at the time of wire bonding to the semiconductor chip. Also, when the storage elastic modulus at 175° C. after curing at 150° C. for one hour is 0.5 MPa or more, the generation of peeling-off of the die-bonding film can be prevented in the humidity resistance solder reflow test, whereby the reliability can be improved. Similarly, it is preferable that the storage elastic modulus of the die-bonding film at 260° C. after curing at 175° C. for one hour is 0.5 MPa or more.

In the die-bonding film, it is preferable that a shear adhering strength between the die-bonding film and an adherend at 175° C. after bonding to the adherend and curing at 150° C. for one hour is 0.3 MPa or more. By this, a sufficient adhering strength can be maintained at the time of wire bonding to the semiconductor chip. As a result of this, shear deformation on the bonding surface between the die-bonding film and the adherend by supersonic vibration or heating can be prevented in performing wire bonding on the semiconductor chip bonded and fixed onto the die-bonding film, whereby the ratio of success of the wire bonding can be improved.

The die-bonding film preferably contains 0.05 wt % or more of a dye. As a result of this, distinction between the die-bonding film and the dicing tape can be made.

The dicing die-bonding film of the present invention includes a dicing tape and the aforesaid die-bonding film that is laminated on the dicing tape. Since the dicing die-bonding film of the present invention is provided with the aforesaid die-bonding film, the generation of air bubbles (voids) at the boundary between the die-bonding film and the adherend such as a substrate can be restrained or made to disappear in the steps of manufacturing a semiconductor device. Also, a sufficient shear adhering strength can be exhibited at a high temperature after the curing, making it possible to manufacture a semiconductor device having a high reliability.

The method for manufacturing a semiconductor device of the present invention comprises:

bonding the die-bonding film of the dicing die-bonding film and a back surface of a semiconductor wafer;

dicing the semiconductor wafer together with the dicing die-bonding film to form a chip-shaped semiconductor element;

picking up the semiconductor element together with the die-bonding film from the dicing die-bonding film;

die-bonding the semiconductor element on an adherend through the die-bonding film; and

performing wire bonding on the semiconductor element.

By the aforesaid manufacturing method, voids can be prevented from staying at the boundary between the die-bonding film and the adherend. Also, a highly reliable semiconductor device in which peeling-off is not generated in the humidity resistance solder reflow test can be manufactured with a good efficiency.

### BRIEF DESCRIPTION OF THE DRAWINGS

FIG. 1 is a schematic sectional view showing a dicing die-bonding film according to one embodiment of the present invention;

FIG. 2 is a schematic sectional view showing another dicing die-bonding film according to the embodiment;

FIG. 3 is a schematic sectional view showing en example in which a semiconductor chip is mounted through a die-bonding film in the dicing die-bonding film;

FIG. 4 is a schematic sectional view showing en example in which a semiconductor chip is three-dimensionally mounted through a die-bonding film in the dicing die-bonding film; and

FIG. 5 is a schematic sectional view showing an example in which two semiconductor chip are three-dimensionally mounted by a die-bonding film through a spacer using the dicing die-bonding film.

### DETAILED DESCRIPTION OF THE PREFERRED EMBODIMENTS

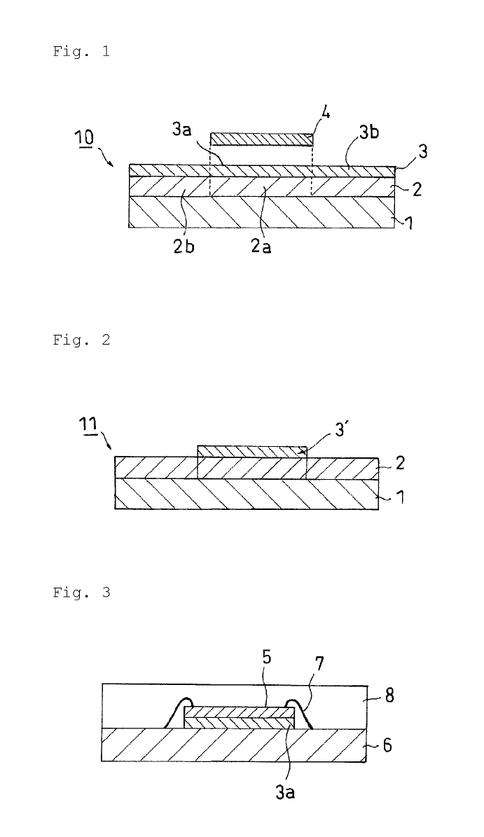

Hereafter, the die-bonding film of the present invention will be described by raising a mode of a dicing die-bonding film as an example. A dicing die-bonding film 10 according to the present embodiment has a structure in which a die-bonding film 3 is laminated on a dicing film (See FIG. 1). The dicing film has a structure in which a pressure-sensitive adhesive layer 2 is laminated on a base material 1. The die-bonding film 3 is laminated on the pressure-sensitive adhesive layer 2 of the dicing film.

### <Die-Bonding Film>

The die-bonding film 3 of the present invention contains a glycidyl-group-containing acrylic copolymer (a) having a weight-average molecular weight of 500,000 or more and a phenolic resin (b), wherein a weight ratio (x/y) of the content x of the copolymer (a) to the content y of the phenolic resin (b) is 5 or more and 30 or less, and the die-bonding film substantially does not contain an epoxy resin having a weight-average molecular weight of 5000 or less.

### (Glycidyl-Group-Containing Acrylic Copolymer (a))

The copolymer (a) is not particularly limited as long as the copolymer (a) is an acrylic copolymer having a weight-average molecular weight of 500,000 or more and having a glycidyl group. A method for introducing the glycidyl group into the copolymer (a) is not particularly limited, so that the glycidyl group may be introduced by copolymerization of a glycidyl-group-containing monomer and other monomer components or may be introduced by preparing a copolymer of acrylic monomers and thereafter allowing this copolymer and a compound having a glycidyl group to react. In consideration of the facility and the like in preparing the copolymer (a), the glycidyl group is preferably introduced by copolymerization of a glycidyl-group-containing monomer and other monomer components. As the glycidyl-group-containing monomer, a monomer having a glycidyl group and having a copolymerizable ethylenic unsaturated bond can be suitably used, and examples thereof include glycidyl acrylate and glycidyl methacrylate. The content of the glycidyl-group-containing monomer in the copolymer (a) may be determined in consideration of the glass transition point and the epoxy value of the intended copolymer (a), and is typically 1 to 20 mol %, preferably 1 to 15 mol %, still more preferably 1 to 10 mol %.

Examples of the other monomers constituting the copolymer (a) include: alkyl acrylates having an alkyl group with a carbon number of 1 to 8 such as methyl acrylate, ethyl acrylate, propyl acrylate, butyl acrylate, pentyl acrylate, and hexyl acrylate; alkyl methacrylates having an alkyl group with a carbon number of 1 to 8 such as methyl methacrylate, ethyl methacrylate, propyl methacrylate, butyl methacrylate, pentyl methacrylate, and hexyl methacrylate; acrylonitrile; styrene; carboxyl group-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride, and itaconic anhydride; hydroxyl group-containing monomers such as 2-hydroxyethyl(meth)acrylate, 2-hydroxypropyl(meth)acrylate, 4-hydroxybutyl(meth)acrylate, 6-hydroxyhexyl (meth)acrylate, 8-hydroxyoctyl(meth)acrylate, 10-hydroxydecyl(meth)acrylate, 12-hydroxylauryl (meth)acrylate, and (4-hydroxylmethylcyclohexyl)methyl (meth)acrylate; sulfonic acid group containing monomers such as styrenesulfonic acid, allylsulfonic acid, 2-(meth)acrylamide-2-methylpropanesulfonic acid, (meth) acrylamidepropanesulfonic acid, sulfopropyl (meth)acrylate, and (meth)acryloyloxynaphthalenesulfonic acid; phosphoric acid group containing monomers such as 2-hydroxyethylacryloyl phosphate and others. These other monomers may be used either as one kind or by combination of two or more kinds. Among the aforesaid other monomers, at least one kind selected from alkyl acrylates having an alkyl group with a carbon number of 1 to 4 and alkyl methacrylates having an alkyl group with a carbon number of 1 to 4, as well as acrylonitrile are preferable; at least one kind selected from ethyl acrylate and butyl acrylate as well as acrylonitrile are more preferable; and it is particularly preferable to contain all of these.

The mixing ratio of the monomers constituting the copolymer (a) is preferably adjusted in consideration of the glass transition point and the epoxy value of the copolymer (a). A method for polymerizing the copolymer (a) is not particularly limited, so that, for example, various conventionally known methods such as the solution polymerization method, the bulk polymerization method, the suspension polymerization method, and the emulsion polymerization method can be adopted.

When the copolymer (a) contains acrylonitrile, the acrylonitrile is preferably contained at a ratio of 15 wt % or more, more preferably 20 wt % or more, relative to the total weight of the copolymer (a). When the content of acrylonitrile in the copolymer (a) is less than 15 wt %, the cohesive strength at a high temperature (for example, 150° C. to 260° C.) becomes weak, and a sufficient shear adhering strength may not be exhibited in some cases.

The glass transition point (Tg) of the copolymer (a) is not particularly limited as long as a suitable bonding property is obtained between the die-bonding film and the silicon wafer; however, the glass transition point is preferably −15° C. or higher and 40° C. or lower, more preferably −5° C. or higher and 35° C. or lower. When the glass transition point is lower than −15° C., a tack property is generated in the copolymer (a) at an ordinary temperature, and the handling property may become poor in some cases. On the other hand, when the glass transition point exceeds 40° C., there is a fear that the adhering strength to the silicon wafer may decrease.

The weight-average molecular weight of the copolymer (a) may be 500,000 or more, preferably 700,000 or more. When the weight-average molecular weight of the copolymer (a) is less than 500,000, the cohesive strength at a high temperature becomes weak, so that a sufficient shear adhering strength may not be obtained in some cases. On the other hand, the upper limit of the weight-average molecular weight of the copolymer (a) is not particularly limited; however, the upper limit may be 2,000,000, preferably 1,800,000, in consideration of the solubility at the time of preparing the die-bonding film and the adhering strength to the silicon wafer. Here, in the present specification, the weight-average molecular weight means a polystyrene-converted value using a calibration line with standard polystyrene by gel permeation chromatography (GPC).

The epoxy value of the copolymer (a) is preferably 0.15 e.g./kg or more and 0.65 e.g./kg or less, more preferably 0.2 e.g./kg or more and 0.5 e.g./kg or less. When the epoxy value of the copolymer (a) is 0.15 e.g./kg or more, a sufficient elastic modulus can be obtained at a high temperature after curing. When the epoxy value of the copolymer (a) is 0.65 e.g./kg or less, the storage property at room temperature can be maintained. Here, calculation of the epoxy value will be described in detail in the Examples.

The phenol resin is a resin acting as a curing agent for the copolymer (a). Examples thereof include Novolak type phenol resins such as phenol Novolak resin, phenol biphenyl resin, phenol aralkyl resin, cresol Novolak resin, tert-butylphenol Novolak resin and nonylphenol Novolak resin; resol type phenol resins; and polyoxystyrenes such as poly(p-oxystyrene). These may be used alone or in combination of two or more thereof. Among these phenol resins, the biphenyl type phenol novolak resin represented by the following chemical formula and the phenolaralkyl resin are preferable, since the connection reliability of the semiconductor device can be improved.

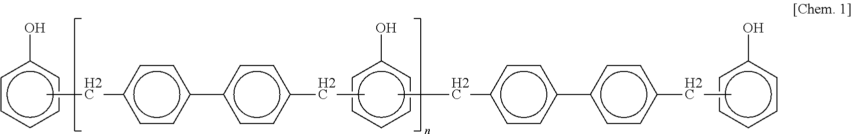

In the chemical formula, n is a natural number of 0 to 10, and preferably a natural number of 0 to 5. By making setting the n within the above-described range, the fluidity of die-bonding film 3 can be secured.

As the phenolic resin (b), in view of the control of heat resistance and reactivity, a resin having a hydroxyl equivalent of 100 g/eq or more and 500 g/eq or less is preferable, and a resin having a hydroxyl equivalent of 100 g/eq or more and 400 g/eq or less is more preferable.

The weight-average molecular weight of the aforesaid phenolic resin is not particularly limited as long as the thermosetting property of the copolymer (a) is obtained; however, the weight-average molecular weight is preferably within a range from 300 to 3000, more preferably within a range from 350 to 2000. When the weight-average molecular weight is less than 300, thermal curing of the copolymer (a) is insufficient, and sufficient toughness may not be obtained. On the other hand, when the weight-average molecular weight is larger than 3000, the die-bonding film 3 is highly viscous, and workability during production of the die-bonding film may deteriorate.

The weight ratio (x/y) of the content x of the copolymer (a) to the content y of the phenolic resin (b) may be 5 or more and 30 or less, preferably 5.5 or more and 25 or less. When the weight ratio is less than 5, unreacted phenolic resin (b) affects the reliability in the humidity resistance solder reflow test. Also, when the weight ratio exceeds 30, the cohesive strength at the high temperature after the curing of the die-bonding film decreases, so that a sufficient shear adhering strength cannot be obtained.

When the die-bonding film 3 of the present invention is cross-linked to a certain degree in advance, a polyfunctional compound that reacts with a functional group or the like at the terminal end of the molecular chain of the polymer may be added as a cross-linking agent in preparation. By this, the bonding characteristics at a high temperature can be improved, and the heat resistance can be improved.

As the cross-linking agent, a conventionally known one can be adopted. In particular, a polyisocyanate compound such as tolylene diisocyanate, diphenylmethane diisocyanate, p-phenylene diisocyanate, 1,5-naphthalene diisocyanate, or an adduct of polyhydric alcohol and diisocyanate is more preferable. Typically, the amount of addition of the cross-linking agent is preferably 0.05 to 7 parts by weight relative to 100 parts by weight of the polymer. When the amount of the cross-linking agent exceeds 7 parts by weight, the adhering strength decreases, so that it is not preferable. On the other hand, when the amount of the cross-linking agent is less than 0.05 parts by weight, the cohesive strength becomes insufficient, so that it is not preferable.

To the die-bonding film of the present invention, a filler can be suitably blended in addition to the aforesaid resin. Examples of the filler include an inorganic filler and an organic filler. The inorganic filler is preferable from the viewpoints of the handing property, improvement of the heat conductivity, adjustment of the melt viscosity, and impartment of a thyrotrophic property.

The inorganic filler is not especially limited, and examples thereof include silica, aluminum hydroxide, calcium hydroxide, magnesium hydroxide, antimony trioxide, calcium carbonate, magnesium carbonate, calcium silicate, magnesium silicate, calcium oxide, magnesium oxide, aluminum oxide, aluminum nitride, aluminum borate, boron nitride, crystalline silica, and amorphous silica. These may be used either alone or in combination of two or more kinds. From the viewpoint of improvement of the heat conductivity, aluminum oxide, aluminum nitride, boron nitride, crystalline silica, amorphous silica, and the like are preferable. From the viewpoint of a balance with the tackiness of the die-bonding film 3, silica is preferable. Further, examples of the organic filler include polyimide, polyamideimide, polyether ether ketone, polyetterimide, polyesterimide, nylon, and silicone. These may be used either alone or in combination of two or more kinds.

The average particle size of the filler is preferably 0.005 to 10 μm, and more preferably 0.05 to 1 μl. When the average particle size of the filler is 0.005 μm or more, the wettability to the adherend can be made good, and a decrease of the tackiness can be suppressed. On the other hand, by making the average particle size be 10 μm or less, the effect of reinforcing the die-bonding film 3 by adding the filler can be enhanced, and the heat resistance can be improved. Fillers having different average particle sizes from each other may be used in combination. The average particle size of the filler is a value obtained with a light intensity type particle size distribution meter (manufactured by HORIBA, Ltd., device name: LA-910).

The shape of the filler is not especially limited, and a spherical filler and an oval filler can be used, for example.

Also, when it is assumed that the combined weight of the glycidyl-group-containing acrylic copolymer (a) and the phenolic resin (b) is A parts by weight and the weight of the filler is B parts by weight, it is preferable that the ratio B/(A+B) exceeds 0 and is 0.8 or less, more preferably exceeds 0 and is 0.7 or less. When the aforesaid ratio is 0, the reinforcing effect by addition of the filler is not obtained, so that the heat resistance of the die-bonding film 3 may not be improved in some cases. On the other hand, when the aforesaid ratio exceeds 0.8, the wettability and the bonding property to the adherend may decrease.

If necessary, other additives may be incorporated into the die-bonding film 3 of the present invention. Examples thereof include a flame retardant, a silane coupling agent, and an ion trapping agent.

Examples of the flame retardant include antimony trioxide, antimony pentaoxide, and brominated epoxy resin. These may be used alone or in combination of two or more thereof.

Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These may be used alone or in combination of two or more thereof.

Examples of the ion trapping agent include hydrotalcite and bismuth hydroxide. These may be used alone or in combination of two or more thereof.

The thermal curing-accelerating catalyst for the copolymer (a) and the phenol resin is not especially limited, and a preferred example thereof is a salt consisting of any of a triphenylphosphine skeleton, an amine skeleton, a triphenylborane skeleton, a trihalogenborane skeleton, and the like.

In the die-bonding film, it is preferable that the storage elastic modulus thereof at 50° C. before curing is 10 MPa or less, more preferably 8 MPa or less. When the storage elastic modulus at 50° C. before curing is 10 MPa or less, the wettability to the adherend can be ensured, and the adhering strength can be maintained.

It is preferable that the storage elastic modulus of the die-bonding film at 175° C. is 0.1 MPa or more, more preferably 0.2 MPa or more. When the storage elastic modulus at 175° C. is 0.1 MPa or more, a sufficient adhering strength can be maintained at the time of wire bonding to the semiconductor chip.

Also, in the die-bonding film, it is preferable that the storage elastic modulus thereof at 175° C. after curing at 150° C. for one hour is 0.5 MPa or more, more preferably 0.6 MPa or more. When the storage elastic modulus at 175° C. after curing at 150° C. for one hour is 0.5 MPa or more, the generation of peeling-off of the die-bonding film can be prevented in the humidity resistance solder reflow test, whereby the reliability can be improved. For similar reasons, it is preferable that the storage elastic modulus of the die-bonding film at 260° C. after curing at 175° C. for one hour is 0.5 MPa or more.

In the die-bonding film, it is preferable that the shear adhering strength between the die-bonding film and the adherend at 175° C. after bonding to the adherend and curing at 150° C. for one hour is 0.3 MPa or more, more preferably 0.35 MPa or more. By this, a sufficient adhering strength can be maintained at the time of wire bonding to the semiconductor chip. As a result of this, shear deformation on the bonding surface between the die-bonding film and the adherend by supersonic vibration or heating can be prevented in performing wire bonding on the semiconductor chip bonded and fixed onto the die-bonding film, whereby the ratio of success of the wire bonding can be improved. Here, a method for measuring the shear adhering strength between the die-bonding film and the adherend will be described in the Examples.

The die-bonding film preferably has one property among the above-described various storage elastic moduli and shear adhering strength, and more preferably has a combination of two or more properties.

The thickness of the die-bonding film 3 (in the case that the film is a laminate, the total thickness thereof) is not particularly limited, and is, for example, from about 5 to 100 μm, preferably from about 5 to 50 μm.

The die-bonding film may have a configuration consisting only of a single adhesive layer, for example. It may have a multi-layered structure of two layers or more in which thermoplastic resins having different glass transition temperatures and thermosetting resins having different thermal curing temperatures are appropriately combined. Because cutting water is used in the dicing step of a semiconductor wafer, the die-bonding film absorbs moisture, and may have a water content exceeding that in a normal state. When the die-bonding film and the like with such a high water content are adhered to a substrate, water vapor builds up on the adhering interface in the step of after curing, and floating may occur. Therefore, by making the die-bonding film have a configuration in which a core material having high moisture permeability is sandwiched between adhesive layers, water vapor diffuses through the film in the step of after curing, and such a problem can be avoided. From such a viewpoint, the die-bonding film may have a multi-layered structure in which the adhesive layer is formed on one surface or both surfaces of the core material.

Examples of the core material include a film such as a polyimide film, a polyester film, a polyethylene terephthalate film, a polyethylene naphthalate film, or a polycarbonate film, a resin substrate that is reinforced with glass fibers or plastic nonwoven fibers, a mirror silicon wafer, a silicon substrate, and a glass substrate.

The die-bonding film 3 is preferably protected by a separator (not shown). The separator has a function as a protecting material that protects the die-bonding film 3 until they are practically used. Further, the separator can be used as a supporting base material when transferring the die-bonding films 3, 3′ to the dicing film. The separator is peeled when pasting a workpiece onto the die-bonding film. Polyethylenetelephthalate (PET), polyethylene, polypropylene, a plastic film, a paper, etc. whose surface is coated with a peeling agent such as a fluorine based peeling agent and a long chain alkylacrylate based peeling agent can be also used as the separator.

Also, the humidity absorption ratio of the die-bonding film 3 after thermosetting is preferably 1 w % or less, more preferably 0.8 wt % or less. When the humidity absorption ratio is 1 wt % or less, generation of voids can be prevented, for example, in the reflow process. Adjustment of the humidity absorption ratio can be made, for example, by changing the amount of addition of the inorganic filler or the like. Also, the humidity absorption ratio is a value calculated on the basis of the weight change when the die-bonding film is left to stand in an atmosphere of 85° C. with 60% RH for 168 hours.

The dicing die-bonding film according to the present invention may have a configuration of a dicing die-bonding film 11 in which a die-bonding film 3′ is laminated only onto a semiconductor wafer attaching part as shown in FIG. 2, in addition to the configuration of the die-bonding film 3 shown in FIG. 1.

### <Dicing Film>

The dicing film constituting the dicing die-bonding films 10, 11 has a structure in which a pressure-sensitive adhesive layer 2 is laminated on a base material 1. Hereafter, the base material and the pressure-sensitive adhesive layer will be described in this order.

### (Base Material)

The base material 1 serves as a base body for strength of the dicing die-bonding films 10 and 11. Examples thereof include polyolefin such as low-density polyethylene, straight chain polyethylene, intermediate-density polyethylene, high-density polyethylene, very low-density polyethylene, random copolymer polypropylene, block copolymer polypropylene, homopolypropylene, polybutene, and polymethylpentene; an ethylene-vinylacetate copolymer; an ionomer resin; an ethylene(meth)acrylic acid copolymer; an ethylene(meth)acrylic acid ester (random or alternating) copolymer; an ethylene-butene copolymer; an ethylene-hexene copolymer; polyurethane; polyester such as polyethyleneterephthalate and polyethylenenaphthalate; polycarbonate; polyetheretherketone; polyimide; polyetherimide; polyamide; whole aromatic polyamides; polyphenylsulfide; aramid (paper); glass; glass cloth; a fluorine resin; polyvinyl chloride; polyvinylidene chloride; a cellulose resin; a silicone resin; metal (foil); and paper. When the pressure-sensitive adhesive layer 2 is of an ultraviolet-ray curing-type, the base material 1 preferably has transparency to an ultraviolet ray.

Further, the material of the base material 1 includes a polymer such as a cross-linked body of the above resins. The above plastic film may be also used unstreched, or may be also used on which a monoaxial or a biaxial stretching treatment is performed depending on necessity. According to resin sheets in which heat shrinkable properties are given by the stretching treatment, etc., the adhesive area of the pressure-sensitive adhesive layer 2 and the die-bonding films 3, 3′ is reduced by thermally shrinking the base material 1 after dicing, and the collection of the semiconductor chips can be facilitated.

A known surface treatment such as a chemical or physical treatment such as a chromate treatment, ozone exposure, flame exposure, high voltage electric exposure, and an ionized ultraviolet treatment, and a coating treatment by an undercoating agent (for example, a tacky substance described later) can be performed on the surface of the base material 1 in order to improve adhesiveness, holding properties, etc. with the adjacent layer.

The same type or different type of base material can be appropriately selected and used as the base material 1, and a base material in which a plurality of types are blended can be used depending on necessity. Further, a vapor-deposited layer of a conductive substance composed of a metal, an alloy, an oxide thereof, etc. and having a thickness of about 30 to 500 angstrom can be provided on the base material 1 in order to give an antistatic function to the base material 1. The base material 1 may be a single layer or a multi layer of two or more types.

The thickness of the base material 1 can be appropriately decided without limitation particularly. However, it is generally about 5 to 200 μm.

### (Pressure-Sensitive Adhesive Layer)

The pressure-sensitive adhesive layer 2 is constituted by containing a ultraviolet curable pressure-sensitive adhesive. The ultraviolet curable pressure-sensitive adhesive can easily decrease its adhesive strength by increasing the degree of crosslinking by irradiation with ultraviolet. By radiating only a part 2a corresponding to the semiconductor wafer attaching part of the pressure-sensitive adhesive layer 2 shown in FIG. 1, a difference of the adhesive strength to another part 2b can be also provided.

Further, by curing the ultraviolet curable pressure-sensitive adhesive layer 2 with the die-bonding film 3′ shown in FIG. 2, the part 2a in which the adhesive strength is remarkably decreased can be formed easily. Because the die-bonding film 3′ is bonded to the part 2a in which the adhesive strength is decreased by curing, the interface of the part 2a of the pressure-sensitive adhesive layer 2 and the die-bonding film 3′ has a characteristic of being easily peeled during pickup. On the other hand, the part not radiated by ultraviolet rays has sufficient adhesive strength, and forms the part 2b.

As described above, in the pressure-sensitive adhesive layer 2 of the dicing die-bonding film 10 shown in FIG. 1, the part 2b formed by a non-cured ultraviolet curable pressure-sensitive adhesive sticks to the die-bonding film 3, and the holding force when dicing can be secured. In such a way, the ultraviolet curable pressure-sensitive adhesive can support the die-bonding film 3 for fixing the semiconductor chip onto an adherend such as a substrate with good balance of adhesion and peeling. In the pressure-sensitive adhesive layer 2 of the dicing die-bonding film 11 shown in FIG. 2, a wafer ring can be fixed to the part 2b (corresponding to the part 2b in FIG. 1). The adherend 6 is not especially limited, and examples thereof include various substrates such as a BGA (Ball Grid Array) substrate, a lead frame, a semiconductor element, and a spacer.

The ultraviolet curable pressure-sensitive adhesive that is used has an ultraviolet curable functional group of a radical reactive carbon-carbon double bond, etc., and adherability. Examples of the ultraviolet curable pressure-sensitive adhesive are an added type ultraviolet curable pressure-sensitive adhesive in which an ultraviolet curable monomer component or an oligomer component is compounded into an acryl pressure-sensitive adhesive or a rubber pressure-sensitive adhesive.

The pressure-sensitive adhesive is preferably an acrylic pressure-sensitive adhesive containing an acrylic polymer as a base polymer in view of clean washing of electronic components such as a semiconductor wafer and glass, which are easily damaged by contamination, with ultrapure water or an organic solvent such as alcohol.

Specific examples of the acryl polymers include an acryl polymer in which acrylate is used as a main monomer component. Examples of the acrylate include alkyl acrylate (for example, a straight chain or branched chain alkyl ester having 1 to 30 carbon atoms, and particularly 4 to 18 carbon atoms in the alkyl group such as methylester, ethylester, propylester, isopropylester, butylester, isobutylester, sec-butylester, t-butylester, pentylester, isopentylester, hexylester, heptylester, octylester, 2-ethylhexylester, isooctylester, nonylester, decylester, isodecylester, undecylester, dodecylester, tridecylester, tetradecylester, hexadecylester, octadecylester, and eicosylester) and cycloalkyl acrylate (for example, cyclopentylester, cyclohexylester, etc.). These monomers may be used alone or two or more types may be used in combination. All of the words including “(meth)” in connection with the present invention have an equivalent meaning.

The acrylic polymer may optionally contain a unit corresponding to a different monomer component copolymerizable with the above-mentioned alkyl ester of (meth)acrylic acid or cycloalkyl ester thereof in order to improve the cohesive force, heat resistance or some other property of the polymer. Examples of such a monomer component include carboxyl-containing monomers such as acrylic acid, methacrylic acid, carboxyethyl(meth)acrylate, carboxypentyl(meth)acrylate, itaconic acid, maleic acid, fumaric acid, and crotonic acid; acid anhydride monomers such as maleic anhydride, and itaconic anhydride; hydroxyl-containing monomers such as 2-hydroxyethyl(meth)acrylate, 2-hydroxypropyl(meth)acrylate, 4-hydroxybutyl (meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxylmethylcyclohexyl)methyl(meth)acrylate; sulfonic acid group containing monomers such as styrenesulfonic acid, allylsulfonic acid, 2-(meth)acrylamide-2-methylpropanesulfonic acid, (meth) acrylamidepropanesulfonic acid, sulfopropyl(meth)acrylate, and (meth) acryloyloxynaphthalenesulfonic acid; phosphoric acid group containing monomers such as 2-hydroxyethylacryloyl phosphate; acrylamide; and acrylonitrile. These copolymerizable monomer components may be used alone or in combination of two or more thereof. The amount of the copolymerizable monomer(s) to be used is preferably 40% or less by weight of all the monomer components.

For crosslinking, the acrylic polymer can also contain multifunctional monomers if necessary as the copolymerizable monomer component. Such multifunctional monomers include hexane diol di(meth)acrylate, (poly)ethylene glycol di(meth)acrylate, (poly)propylene glycol di(meth)acrylate, neopentyl glycol di(meth)acrylate, pentaerythritol di(meth)acrylate, trimethylol propane tri(meth)acrylate, pentaerythritol tri(meth)acrylate, dipentaerythritol hexa(meth)acrylate, epoxy(meth)acrylate, polyester (meth)acrylate, urethane (meth)acrylate etc. These multifunctional monomers can also be used as a mixture of one or more thereof. From the viewpoint of adhesiveness etc., the use amount of the multifunctional monomer is preferably 30 wt % or less based on the whole monomer components.

Preparation of the above acryl polymer can be performed by applying an appropriate manner such as a solution polymerization manner, an emulsion polymerization manner, a bulk polymerization manner, and a suspension polymerization manner to a mixture of one or two or more kinds of component monomers for example. Since the pressure-sensitive adhesive layer preferably has a composition in which the content of low molecular weight materials is suppressed from the viewpoint of prevention of wafer contamination, and since those in which an acryl polymer having a weight-average molecular weight of 300,000 or more, particularly 400,000 to 3,000,000 is as a main component are preferable from such viewpoint, the pressure-sensitive adhesive can be made to be an appropriate cross-linking type with an internal cross-linking manner, an external cross-linking manner, etc.

To increase the number-average molecular weight of the base polymer such as acrylic polymer etc., an external crosslinking agent can be suitably adopted in the pressure-sensitive adhesive. The external crosslinking method is specifically a reaction method that involves adding and reacting a crosslinking agent such as a polyisocyanate compound, epoxy compound, aziridine compound, melamine crosslinking agent, urea resin, anhydrous compound, polyamine, carboxyl group-containing polymer. When the external crosslinking agent is used, the amount of the crosslinking agent to be used is determined suitably depending on balance with the base polymer to be crosslinked and applications thereof as the pressure-sensitive adhesive. Generally, the crosslinking agent is preferably incorporated in an amount of about 5 parts by weight or less, more preferably 0.1 to 5 parts by weight, based on 100 parts by weight of the base polymer. The lower limit of the crosslinking agent is preferably 0.1 parts by weight or more. The pressure-sensitive adhesive may be blended not only with the components described above but also with a wide variety of conventionally known additives such as a tackifier, and aging inhibitor, if necessary.

Examples of the ultraviolet curable monomer component to be compounded include such as an urethane oligomer, urethane(meth)acrylate, trimethylolpropane tri(meth)acrylate, tetramethylolmethane tetra(meth)acrylate, pentaerythritol tri(meth)acrylate, pentaerythritol tetra(meth)acrylate, dipentaerythritol monohydroxypenta(meth)acrylate, dipentaerythritol hexa(meth)acrylate, and 1,4-butane dioldi(meth)acrylate. Further, the ultraviolet curable oligomer component includes various types of oligomers such as an urethane based, a polyether based, a polyester based, a polycarbonate based, and a polybutadiene based oligomer, and its molecular weight is appropriately in a range of about 100 to 30,000. The compounding amount of the ultraviolet ray curable monomer component and the oligomer component can be appropriately determined to an amount in which the adhesive strength of the pressure-sensitive adhesive layer can be decreased depending on the type of the pressure-sensitive adhesive layer. Generally, it is for example 5 to 500 parts by weight, and preferably about 40 to 150 parts by weight based on 100 parts by weight of the base polymer such as an acryl polymer constituting the pressure-sensitive adhesive.

Further, besides the added type ultraviolet curable pressure-sensitive adhesive described above, the ultraviolet curable pressure-sensitive adhesive includes an internal ultraviolet curable pressure-sensitive adhesive using an acryl polymer having a radical reactive carbon-carbon double bond in the polymer side chain, in the main chain, or at the end of the main chain as the base polymer. The internal ultraviolet curable pressure-sensitive adhesives of an internally provided type are preferable because they do not have to contain the oligomer component, etc. that is a low molecular weight component, or most of them do not contain, they can form a pressure-sensitive adhesive layer having a stable layer structure without migrating the oligomer component, etc. in the pressure-sensitive adhesive over time.

The above-mentioned base polymer, which has a carbon-carbon double bond, may be any polymer that has a carbon-carbon double bond and further has viscosity. As such a base polymer, a polymer having an acrylic polymer as a basic skeleton is preferable. Examples of the basic skeleton of the acrylic polymer include the acrylic polymers exemplified above.

The method for introducing a carbon-carbon double bond into any one of the above-mentioned acrylic polymers is not particularly limited, and may be selected from various methods. The introduction of the carbon-carbon double bond into a side chain of the polymer is easier in molecule design. The method is, for example, a method for copolymerizing a monomer having a functional group with an acrylic polymer, and then causing the resultant to condensation-react or addition-react with a compound having a functional group reactive with the above-mentioned functional group and a carbon-carbon double bond while keeping the radial ray curability of the carbon-carbon double bond.

Examples of the combination of these functional groups include a carboxylic acid group and an epoxy group; a carboxylic acid group and an aziridine group; and a hydroxyl group and an isocyanate group. Of these combinations, the combination of a hydroxyl group and an isocyanate group is preferable from the viewpoint of the easiness of reaction tracing. If the above-mentioned acrylic polymer, which has a carbon-carbon double bond, can be produced by the combination of these functional groups, each of the functional groups may be present on any one of the acrylic polymer and the above-mentioned compound. It is preferable for the above-mentioned preferable combination that the acrylic polymer has the hydroxyl group and the above-mentioned compound has the isocyanate group. Examples of the isocyanate compound in this case, which has a carbon-carbon double bond, include methacryloyl isocyanate, 2-methacryloyloxyethyl isocyanate, and m-isopropenyl-α,α-dimethylbenzyl isocyanate. The used acrylic polymer may be an acrylic polymer copolymerized with any one of the hydroxyl-containing monomers exemplified above, or an ether compound such as 2-hydroxyethyl vinyl ether, 4-hydroxybutyl vinyl ether or diethylene glycol monovinyl ether.

The intrinsic type radial ray curable adhesive may be made only of the above-mentioned base polymer (in particular, the acrylic polymer), which has a carbon-carbon double bond. However, the above-mentioned radial ray curable monomer component or oligomer component may be incorporated into the base polymer to such an extent that properties of the adhesive are not deteriorated. The amount of the radial ray curable oligomer component or the like is usually 30 parts or less by weight, preferably from 0 to 10 parts by weight for 100 parts by weight of the base polymer.

In the case that the radial ray curable adhesive is cured with ultraviolet rays or the like, a photopolymerization initiator is incorporated into the adhesive. Examples of the photopolymerization initiator include α-ketol compounds such as 4-(2-hydroxyethoxy)phenyl(2-hydroxy-2-propyl)ketone, α-hydroxy-α,α′-dimethylacetophenone, 2-methyl-2-hydroxypropiophenone, and 1-hydroxycyclohexyl phenyl ketone; acetophenone compounds such as methoxyacetophenone, 2,2-dimethoxy-2-phenylacetophenone, 2,2-diethoxyacetophenone, and 2-methyl-1-[4-(methylthio)-phenyl]-2-morpholinopropane-1; benzoin ether compounds such as benzoin ethyl ether, benzoin isopropyl ether, and anisoin methyl ether; ketal compounds such as benzyl dimethyl ketal; aromatic sulfonyl chloride compounds such as 2-naphthalenesulfonyl chloride; optically active oxime compounds such as 1-phenone-1,1-propanedione-2-(o-ethoxycarbonyl)oxime; benzophenone compounds such as benzophenone, benzoylbenzoic acid, and 3,3′-dimethyl-4-methoxybenzophenone; thioxanthone compound such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketones; acylphosphonoxides; and acylphosphonates. The amount of the photopolymerization initiator to be blended is, for example, from about 0.05 to 20 parts by weight for 100 parts by weight of the acrylic polymer or the like which constitutes the adhesive as a base polymer.

Further, examples of the ultraviolet curing type pressure-sensitive adhesive include a rubber pressure-sensitive adhesive or an acryl pressure-sensitive adhesive which contains an addition-polymerizable compound having two or more unsaturated bonds, a photopolymerizable compound such as alkoxysilane having an epoxy group, and a photopolymerization initiator such as a carbonyl compound, an organic sulfur compound, a peroxide, an amine, and an onium salt compound, which are disclosed in JP-A No. 60-196956.

The method for forming the part 2a in the pressure-sensitive adhesive layer 2 includes a method for forming the ultraviolet curable pressure-sensitive adhesive layer 2 on the base material 1 and then radiating the part 2a with ultraviolet partially and curing. The partial ultraviolet irradiation can be performed through a photo mask in which a pattern is formed which is corresponding to a part 3b, etc. other than the semiconductor wafer attaching part 3a. Further, examples include a method for radiating in a spot manner and curing, etc. The formation of the ultraviolet curable pressure-sensitive adhesive layer 2 can be performed by transferring the pressure-sensitive adhesive layer provided on a separator onto the base material 1. The partial ultraviolet curing can be also performed on the ultraviolet curable pressure-sensitive adhesive layer 2 provided on the separator.

In the pressure-sensitive adhesive layer 2 of the dicing die-bonding film 10, the ultraviolet irradiation may be performed on a part of the pressure-sensitive adhesive layer 2 so that the adhesive strength of the part 2a becomes smaller than the adhesive strength of other parts 2b. That is, the part 2a in which the adhesive strength is decreased can be formed by using those in which the entire or a portion of the part other than the part corresponding to the semiconductor wafer attaching part 3a on at least one face of the base material 1 is shaded, forming the ultraviolet curable pressure-sensitive adhesive layer 2 onto this, then radiating ultraviolet, and curing the part corresponding the semiconductor wafer attaching part 3a. The shading material that can be a photo mask on a supporting film can be manufactured by printing, vapor deposition, etc. Accordingly, the dicing die-bonding film 10 of the present invention can be produced with efficiency.

When curing inhibition due to oxygen occurs during irradiation with an ultraviolet ray, oxygen (air) is desirably shut off from the surface of the ultraviolet-ray curing-type pressure-sensitive adhesive layer 2. Examples of the method for shutting off oxygen (air) include a method for coating the surface of the pressure-sensitive adhesive layer 2 with a separator and a method for irradiating the pressure-sensitive adhesive layer 2 with an ultraviolet ray such as an ultraviolet ray in a nitrogen gas atmosphere.

The thickness of the pressure-sensitive adhesive layer 2 is not especially limited, but it is preferably about 1 to 50 μm from the viewpoints of preventing cracking of the chip cut surface, compatibility of fixing and holding of the adhesive layer, and the like. It is preferably 2 to 30 and further preferably 5 to 25 μm.

### <Method for Producing a Dicing Die-Bonding Film>

The dicing die-bonding films 10, 11 according to the present embodiment can be fabricated, for example, by separately preparing a dicing film and a die-bonding film and finally bonding these. Specifically, the dicing die-bonding films can be prepared according to the following procedure.

First, the base material 1 can be formed as a film by a conventionally known film forming method. As the film forming method, for example, the calendar film forming method, the casting method in an organic solvent, the inflation extrusion method in a closed system, the T-die extrusion method, the coextrusion method, the dry laminate method, or the like can be used.

Next, a pressure-sensitive adhesive composition for forming the pressure-sensitive adhesive layer is prepared. In the pressure-sensitive adhesive composition, resins, additives, and others such as described in the section of the pressure-sensitive adhesive layer are blended. After the prepared pressure-sensitive adhesive composition is applied onto the base material 1 to form an application film, the application film is dried under a predetermined condition (and heated and cross-linked in accordance with the needs) to form the pressure-sensitive adhesive layer 2. A method for application is not particularly limited, so that, for example, roll coating, screen coating, gravure coating, or the like can be used. Also, as the drying condition, for example, the drying temperature is within a range from 80 to 150° C., and the drying time is within a range from 0.5 to 5 minutes. Also, after the pressure-sensitive adhesive composition is applied on a separator to form an application film, the application film may be dried under the aforementioned drying condition to form the pressure-sensitive adhesive layer 2. Thereafter, the pressure-sensitive adhesive layer 2 is bonded onto the base material 1 together with the separator. By this process, the dicing film provided with the base material 1 and the pressure-sensitive adhesive layer 2 is fabricated. Here, it is sufficient that the dicing film is provided with at least a base material and a pressure-sensitive adhesive layer, so that a film having other elements such as a separator is also referred to as the dicing film.

The die-bonding films 3, 3′ are prepared, for example, as follows. First, an adhesive composition which is a material for forming the dicing die-bonding films 3, 3′ is prepared. As described in the section of the die-bonding film, the copolymer (a), the phenolic resin (b), various additives, and others are blended into the adhesive composition.

Next, the prepared adhesive composition is applied to a predetermined thickness on the base material separator to form an application film, followed by drying the application film under a predetermined condition to form the adhesive layer. A method for application is not particularly limited, so that, for example, roll coating, screen coating, gravure coating, or the like can be used. Also, as the drying condition, for example, the drying temperature is within a range from 70 to 160° C., and the drying time is within a range from 1 to 5 minutes. Also, after the adhesive composition is applied on a separator to form an application film, the application film may be dried under the aforementioned drying condition to form the adhesive layer. Thereafter, the adhesive layer is bonded onto the base material separator together with the separator. Here, in the present invention, not only a case in which the die-bonding film is formed of the adhesive layer alone but also a case in which the die-bonding film is formed of the adhesive layer and other elements such as a separator are included.

Subsequently, the separator is peeled off from each of the die-bonding films 3, 3′ and the dicing film, and the die-bonding film and the dicing film are bonded so that the adhesive layer and the pressure-sensitive adhesive layer becomes the bonding surfaces. The bonding may be carried out, for example, by press-bonding. At this time, the laminate temperature is not particularly limited and, for example, 30 to 50° C. are preferable, and 35 to 45° C. are more preferable. Also, the line pressure is not particularly limited and, for example, 0.1 to 20 kgf/cm is preferable, and 1 to 10 kgf/cm is more preferable. Next, the base material separator on the adhesive layer is peeled off, whereby the dicing die-bonding film according to the present embodiment is obtained.

### (Method for Manufacturing a Semiconductor Device)

Next, a method for manufacturing a semiconductor device using the dicing die-bonding film 10 according to the present embodiment is explained below.

First, as shown in FIG. 1, a semiconductor wafer 4 is press-bonded to a semiconductor wafer attaching part 3a of the adhesive layer 3 in the dicing die-bonding film 10 and is fixed by adhering and holding (a bonding step). This step is performed while pressing the semiconductor wafer 4 by a pressing means such as a pressure roll.

Next, the dicing of the semiconductor wafer 4 is performed. Accordingly, the semiconductor wafer 4 is cut into a prescribed size and individualized, and a semiconductor chip 5 is produced (a dicing step). The dicing is performed following a normal method from the circuit face side of the semiconductor wafer 4, for example. Further, the present step can adopt such as a cutting method called full-cut that forms a slit in the dicing die-bonding film 10. The dicing apparatus used in the present step is not particularly limited, and a conventionally known apparatus can be used. Further, because the semiconductor wafer 4 is adhered and fixed by the dicing die-bonding film 10, chip crack and chip fly can be suppressed, and at the same time the damage of the semiconductor wafer can be also suppressed.

Pickup of the semiconductor chip 5 is performed in order to peel a semiconductor chip 5 that is adhered and fixed to the dicing die-bonding film 10 (a pickup step). The method for picking up is not particularly limited, and conventionally known various methods can be adopted. Examples include a method for pushing up the individual semiconductor chip 5 from the dicing die-bonding 10 side with a needle and picking up the pushed semiconductor chip 5 with a picking-up apparatus.

The pickup is performed after irradiating the pressure-sensitive adhesive layer 2 with an ultraviolet ray when the pressure-sensitive adhesive layer 2 is of an ultraviolet-ray curing-type. Accordingly, the adhesive strength of the pressure-sensitive adhesive layer 2 to the adhesive layer 3a decreases, and the peeling of the semiconductor chip 5 becomes easy. As a result, picking up becomes possible without damaging the semiconductor chip 5. The condition such as irradiation intensity and irradiation time when irradiating an ultraviolet ray is not particularly limited, and it may be appropriately set depending on necessity. Further, the light source as described above can be used as a light source used in the ultraviolet irradiation.

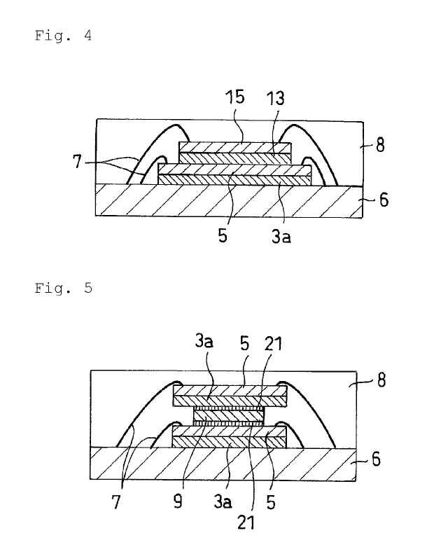

Next, as shown in FIG. 3, the semiconductor chip 5 that is formed by dicing is die-bonded to an adherend 6 with the die-bonding film 3a interposed in between (a die-bonding step). As the adherend 6, a lead frame, a TAB film, a substrate, a separately prepared semiconductor chip, or the like can be used. The adherend 6 may be a deformable-type adherend that is easily deformed, or may be a non-deformable-type adherend (semiconductor wafer or the like) that is hardly deformed.

As the substrate, a conventionally known one can be used. Also, as the lead frame, a metal lead frame such as a Cu lead frame or a 42 Alloy lead frame, or an organic substrate made of glass epoxy, BT (bismaleimide-triazine), polyimide, or the like can be used. However, the present invention is not limited to these, so that a circuit substrate usable by mounting a semiconductor element and electrically connecting to the semiconductor element is also included.

The die-bonding is performed by press-bonding. The condition of die-bonding is not especially limited, and can be set appropriately as necessary. Specifically, the die-bonding can be performed at a die-bonding temperature of 80 to 160° C., a bonding pressure of 5 to 15 N, and a bonding time of 1 to 10 seconds, for example.

Next, the semiconductor chip 5 and the adherend 6 are adhered to each other by thermally curing the die-bonding film 3a by performing a heat treatment on the film. The heat treatment condition is preferably a temperature of 80 to 180° C., and a heating time of 0.1 to 24 hours, preferably 0.1 to 4 hours, and more preferably 0.1 to 1 hour.

Then, a wire bonding step is performed, in which the tip of the terminal part (inner lead) of the adherend 6 and an electrode pad (not shown in the drawings) on the semiconductor chip 5 are electrically connected to each other with a bonding wire 7 (a wire bonding step). The bonding wires 7 may be, for example, gold wires, aluminum wires, or copper wires. The temperature when the wire bonding is performed is from 80 to 250° C., preferably from 80 to 220° C. The heating time is from several seconds to several minutes. The connection of the wires is performed by using a combination of vibration energy based on ultrasonic waves with compression energy based on the application of pressure in the state that the wires are heated to a temperature in the above-mentioned range.

The wire bonding step may be performed without thermally curing the die-bonding film 3 by a heat treatment. In this case, the shear adhering strength of the die-bonding film 3a to the adherend 6 at 25° C. is preferably 0.2 MPa or more, and more preferably 0.2 to 10 MPa. By making the shear adhering strength be 0.2 MPa or more, the shear deformation caused by ultrasonic vibration or heating in this step does not occur at the adhering face between the die-bonding film 3a and the semiconductor chip 5 or the adherend 6 even when the wire bonding step is performed without thermally curing the die-bonding film 3a. That is, the semiconductor element does not move due to the ultrasonic vibration during wire bonding, and accordingly, the success rate of wire bonding is prevented from decreasing.

The uncured die-bonding film 3a is not completely thermally cured even when the wire bonding step is performed. Further, the shear adhering strength of the die-bonding film 3a is required to be 0.2 MPa or more even in a temperature range of 80 to 250° C. When the shear adhering strength is less than 0.2 MPa in this temperature range, the semiconductor element moves by the ultrasonic vibration during wire bonding and wire bonding cannot be performed, and therefore the yield decreases.

Next, a sealing step of sealing the semiconductor chip 5 with a sealing resin 8 is performed. The present step is performed by molding the sealing resin with a mold or die. The sealing resin 8 may be, for example, an epoxy resin. The heating for the resin-sealing is performed usually at 175° C. for 60 to 90 seconds. In the invention, however, the heating is not limited to this, and may be performed, for example at 165 to 185° C. for several minutes. With this operation, the sealing resin is cured, and the die-bonding film 3a is also thermally cured if it has not been thermally cured. That is, in the present invention, the die-bonding film 3a can be adhered by thermal curing in this step even if a post curing step that is described later is not performed, and the present invention can contribute to reduction in the number of manufacturing steps and shortening of the manufacturing period of a semiconductor device.

In the post-curing step, the sealing resin 8, which is not sufficiently cured in the sealing step, is completely cured. Even if the die-bonding film 3a is not completely cured in the step of sealing, the die-bonding film 3a and sealing resin 8 can be completely cured in the present step. The heating temperature in the present step is varied dependently on the kind of the sealing resin, and is, for example, in the range of 165 to 185° C. The heating time is from about 0.5 to 8 hours.

The dicing die-bonding film of the invention also can be preferably used in the case of three-dimensional mounting also in which plural semiconductor chips are laminated, as illustrated in FIG. 4. FIG. 4 is a schematic sectional view illustrating an example wherein semiconductor chips are three-dimensionally mounted through a die-bonding film. In the case of the three-dimensional mounting illustrated in FIG. 4, at least one die-bonding film 3a cut out so as to have a size equal to that of a semiconductor chip 5 is bonded to a adherend 6, and then the semiconductor chip 5 is bonded onto the adherend 6 through the die-bonding film 3a so as to direct its wire bonding face upwards. Next, a die-bonding film 13 is bonded onto the semiconductor chip 5 avoiding its electrode pad portions. Furthermore, another semiconductor chip 15 is bonded onto the die-bonding film 13 so as to direct its wire bonding face upwards. After that, the strength in high temperature is increased by adhering and fixing the die-bonding films 3a and 13 by thermally curing them. As the heating condition, the same as described above, the temperature is preferably in a range of 80 to 200° C. and the heating time is preferably in a range of 0.1 to 24 hours.

In the present invention, the die-bonding films 3a and 13 may be simply die-bonded without thermal curing. After that, wire bonding may be performed without the heating step, the semiconductor chip may be sealed with a sealing resin, and the sealing resin may be post cured.

Next, the wire bonding step is performed. With this operation, an electrode pad of each of the semiconductor chip 5 and another semiconductor chip 15 and the adherend 6 are electrically connected to each other with a bonding wire 7. This step is carried out without going through a heating step of the die-bonding films 3a and 13.

Then, the sealing step of sealing the semiconductor chip 5 and the like with the sealing resin 8 is performed, and the sealing resin is thermally cured. At the same time, when thermal curing is not performed, the adherend 6 and the semiconductor chip 5 are adhered and fixed to each other by thermally curing the die-bonding film 3a. Further, the semiconductor chip 5 and the other semiconductor chip 15 are adhered and fixed to each other by thermally curing the die-bonding film 13. After the sealing step, an after-curing step may be performed.

In the case of the three-dimensional mounting of the semiconductor chips, the production process is simplified and the yield is improved since heating treatment by heating the die-bonding films 3a and 13 is not conducted. Furthermore, the adherend 6 is not warped, and the semiconductor chips 5 and 15 are not cracked; thus, the semiconductor element can be made still thinner.

Three-dimensional mounting may performed in which semiconductor chips are laminated through die-bonding films so as to interpose a spacer between the semiconductor chips, as illustrated in FIG. 5. FIG. 5 is a schematic sectional view illustrating an example wherein two semiconductor chips are three-dimensionally mounted through die-bonding films so as to interpose a spacer between the chips.

In the case of the three-dimensional mounting illustrated in FIG. 5, first, a die-bonding film 3a, a semiconductor chip 5, and a die-bonding film 21 are successively laminated on the adherend 6 to bond these members. Furthermore, on the die-bonding film 21 are successively laminated a spacer 9, another die-bonding film 21, another die-bonding film 3a, and another semiconductor chip 5 to bond these members. After that, the strength in high temperature is increased by adhering and fixing the die-bonding films 3a and 21 by thermally curing them. As the heating condition, the same as described above, the temperature is preferably in a range of 80 to 200° C. and the heating time is preferably in a range of 0.1 to 24 hours.

In the present invention, the die-bonding films 3a and 21 may be simply die-bonded without thermal curing. After that, wire bonding may be performed without going through the heating step, the semiconductor chip may be sealed with a sealing resin, and the sealing resin may be post cured.

Next, as shown in FIG. 5, the wire bonding step is performed. With this operation, an electrode pad of the semiconductor chip 5 and the adherend 6 are electrically connected to each other with the bonding wire 7. This step is carried out without going through a heating step of the die-bonding films 3a and 21.

Then, the sealing step of sealing the semiconductor chip 5 with the sealing resin 8 is performed. The sealing resin 8 is thermally cured, and when the die-bonding films 3a and 21 are uncured, the adherend 6 and the semiconductor chip 5, and the semiconductor chip 5 and a spacer 9, are adhered and fixed to each other by thermally curing the die-bonding films 3a and 21. In this way, a semiconductor package is obtained. The sealing step is preferably performed by a package sealing method wherein only the semiconductor chip 5 is sealed. The sealing is performed to protect the semiconductor chips 5 adhered onto the adhesive sheet(s). The method therefor is typically a method for using the sealing resin 8 and molding the resin 8 in a metal mold. At this time, it is general to use a metal mold composed of an upper metal mold part and a lower metal mold part and having plural cavities to seal simultaneously. The heating temperature at the time of the sealing preferably ranges, for example, from 170 to 180° C. After the sealing step, an after-curing step may be performed.

The spacer 9 is not particularly limited, and may be made of, for example, a silicon chip or polyimide film and the like known in the prior art. The spacer may be a core member. The core member is not particularly limited, and may be a core member known in the prior art. Specific examples thereof include films (such as a polyimide film, a polyester film, a polyethylene terephthalate film, a polyethylene naphthalate film, a polycarbonate film and the like), resin substrates each reinforced with glass fiber or plastic nonwoven fiber, mirror silicon wafers, silicon substrates, and glass adherends.

### (Other Matters)

When semiconductor elements are three-dimensionally mounted on the above-mentioned adherend, a buffer court film is formed on the side where the circuit of the semiconductor element is formed. The buffer court film includes high-temperature resins such as the nitride silicon films or the polyimide resins for instance.

Moreover, when semiconductor elements are three-dimensionally mounted, the die-bonding film used in each steps is not limited to the same composition and can be properly changed according to the manufacturing condition, the usage, and the like.

The lamination methods described in the above-mentioned embodiments are mere exemplifications, and can be changed appropriately, if necessary. For example, in the method for manufacturing a semiconductor device described referring to FIG. 4, a semiconductor element provided at third step or more can also be laminated by the lamination method described referring to FIG. 5

Moreover, in the above-mentioned embodiment, the wire bonding process is done in bulk after semiconductor elements are accumulated to the adherend. Present invention, however, is not limited to the embodiment. For instance, it is also possible to do the wire bonding process every time the semiconductor element is accumulated on the adherend.

### EXAMPLES

Preferred examples of the present invention are explained in detail below. However, materials, compounded amounts, and the like described in these examples are not meant to limit the scope of the present invention as long as there is no special restrictive description, and they are only explanatory examples. Further, “part(s)” in examples means “part(s) by weight”.

### Example 1

An adhesive composition having a concentration of 23.6 wt % was prepared by dissolving 100 parts of an acrylic acid ester based polymer (manufactured by Negami Industry Co., Ltd., 1.9 mol % of glycidyl acrylate) containing acrylonitrile-ethyl acrylate-butyl acrylate as a major component and having an epoxy value of 0.18, a glass transition point (Tg) of 30° C., and a weight-average molecular weight of 1,100,000 as the glycidyl-group-containing acrylic copolymer (a) and 17.5 parts of phenolic resin (manufactured by Meiwa Kasei Co., Ltd., “MEH7651”) as the phenolic resin (b) into methyl ethyl ketone.

This adhesive composition was applied onto a release treatment film, as a peeling-off liner, made of a polyethylene terephthalate film having a thickness of 50 and which was subjected to a silicone release treatment, followed by drying at 130° C. for 2 minutes. By this process, a die-bonding film having a thickness of 25 μm was prepared.

### Example 2

A die-bonding film was prepared in the same manner as in Example 1 except that an adhesive composition having a concentration of 23.6 wt % was prepared by dissolving 100 parts of an acrylic acid ester based polymer (manufactured by Negami Industry Co., Ltd., 2.3 mol % of glycidyl acrylate) containing acrylonitrile-ethyl acrylate-butyl acrylate as a major component and having an epoxy value of 0.22, a glass transition point (Tg) of 15° C., and a weight-average molecular weight of 800,000 as the glycidyl-group-containing acrylic copolymer (a) and 12.5 parts of phenolic resin (manufactured by Meiwa Kasei Co., Ltd., “MEH7851”) as the phenolic resin (b) into methyl ethyl ketone, and further dispersing 40 parts of spherical silica (manufactured by Admatechs Co., Ltd., “SO-25R”) having an average particle size of 500 nm.

### Example 3

A die-bonding film was prepared in the same manner as in Example 1 except that an adhesive composition having a concentration of 23.6 wt % was prepared by dissolving 100 parts of an acrylic acid ester based polymer (manufactured by Negami Industry Co., Ltd., 4.5 mol % of glycidyl acrylate) containing acrylonitrile-ethyl acrylate-butyl acrylate as a major component and having an epoxy value of 0.42, a glass transition point (Tg) of 15° C., and a weight-average molecular weight of 800,000 as the glycidyl-group-containing acrylic copolymer (a) and 6.5 parts of phenolic resin (manufactured by Meiwa Kasei Co., Ltd., “MEH7851”) as the phenolic resin (b) into methyl ethyl ketone, and further dispersing 40 parts of spherical silica (manufactured by Admatechs Co., Ltd., “SO-25R”) having an average particle size of 500 nm.

### Example 4

A die-bonding film was prepared in the same manner as in Example 1 except that an adhesive composition having a concentration of 23.6 wt % was prepared by dissolving 100 parts of an acrylic acid ester based polymer (manufactured by Negami Industry Co., Ltd., 6.4 mol % of glycidyl acrylate) containing acrylonitrile-ethyl acrylate-butyl acrylate as a major component and having an epoxy value of 0.62, a glass transition point (Tg) of 0° C., and a weight-average molecular weight of 600,000 as the glycidyl-group-containing acrylic copolymer (a) and 4.1 parts of phenolic resin (manufactured by Meiwa Kasei Co., Ltd., “MEH7851”) as the phenolic resin (b) into methyl ethyl ketone, and further dispersing 50 parts of spherical silica (manufactured by Admatechs Co., Ltd., “SO-25R”) having an average particle size of 500 nm.

### Example 5

A die-bonding film was prepared in the same manner as in Example 1 except that an adhesive composition having a concentration of 23.6 wt % was prepared by dissolving 100 parts of an acrylic acid ester based polymer (manufactured by Negami Industry Co., Ltd., 6.4 mol % of glycidyl acrylate) containing acrylonitrile-ethyl acrylate-butyl acrylate as a major component and having an epoxy value of 0.62, a glass transition point (Tg) of 20° C., and a weight-average molecular weight of 800,000 as the glycidyl-group-containing acrylic copolymer (a) and 17.5 parts of phenolic resin (manufactured by Meiwa Kasei Co., Ltd., “MEH7851”) as the phenolic resin (b) into methyl ethyl ketone, and further dispersing 10 parts of spherical silica (manufactured by Admatechs Co., Ltd., “SO-25R”) having an average particle size of 500 nm.

### Example 6

A die-bonding film was prepared in the same manner as in Example 1 except that an adhesive composition having a concentration of 23.6 wt % was prepared by dissolving 100 parts of an acrylic acid ester based polymer (manufactured by Negami Industry Co., Ltd., 1.9 mol % of glycidyl acrylate) containing acrylonitrile-ethyl acrylate-butyl acrylate as a major component and having an epoxy value of 0.18, a glass transition point (Tg) of 0° C., and a weight-average molecular weight of 1,000,000 as the glycidyl-group-containing acrylic copolymer (a) and 4.1 parts of phenolic resin (manufactured by Meiwa Kasei Co., Ltd., “MEH7851”) as the phenolic resin (b) into methyl ethyl ketone, and further dispersing 20 parts of spherical silica (manufactured by Admatechs Co., Ltd., “SO-25R”) having an average particle size of 500 nm.

### Comparative Example 1

A die-bonding film was prepared in the same manner as in Example 1 except that an adhesive composition having a concentration of 23.6 wt % was prepared by dissolving 100 parts of an acrylic acid ester based polymer (manufactured by Negami Industry Co., Ltd., 1.9 mol % of glycidyl acrylate) containing acrylonitrile-ethyl acrylate-butyl acrylate as a major component and having an epoxy value of 0.18, a glass transition point (Tg) of 30° C., and a weight-average molecular weight of 800,000 as the glycidyl-group-containing acrylic copolymer (a), 10 parts of phenolic resin (manufactured by Meiwa Kasei Co., Ltd., “MEH7851”) as the phenolic resin (b) and 7.5 parts of an epoxy resin (manufactured by DIC Co., Ltd., “HP-7200H”) having a weight-average molecular weight of 1000 into methyl ethyl ketone.

### Comparative Example 2

A die-bonding film was prepared in the same manner as in Example 1 except that an adhesive composition having a concentration of 23.6 wt % was prepared by dissolving 100 parts of an acrylic acid ester based polymer (manufactured by Negami Industry Co., Ltd., 4.5 mol % of glycidyl acrylate) containing acrylonitrile-ethyl acrylate-butyl acrylate as a major component and having an epoxy value of 0.42, a glass transition point (Tg) of 15° C., and a weight-average molecular weight of 800,000 as the glycidyl-group-containing acrylic copolymer (a), 3.3 parts of phenolic resin (manufactured by Meiwa Kasei Co., Ltd., “MEH7851”) as the phenolic resin (b) and 3.2 parts of an epoxy resin (manufactured by DIC Co., Ltd., “HP-7200H”) having a weight-average molecular weight of 1000 into methyl ethyl ketone, and further dispersing 40 parts of spherical silica (manufactured by Admatechs Co., Ltd., “SO-25R”) having an average particle size of 500 nm.

### Comparative Example 3

A die-bonding film was prepared in the same manner as in Example 1 except that an adhesive composition having a concentration of 23.6 wt % was prepared by dissolving 100 parts of an acrylic acid ester based polymer (manufactured by Negami Industry Co., Ltd., 1.9 mol % of glycidyl acrylate) containing acrylonitrile-ethyl acrylate-butyl acrylate as a major component and having an epoxy value of 0.18, a glass transition point (Tg) of 30° C., and a weight-average molecular weight of 800,000 as the glycidyl-group-containing acrylic copolymer (a) and 25 parts of phenolic resin (manufactured by Meiwa Kasei Co., Ltd., “MEH7851”) as the phenolic resin (b) into methyl ethyl ketone.

### Comparative Example 4

A die-bonding film was prepared in the same manner as in Example 1 except that an adhesive composition having a concentration of 23.6 wt % was prepared by dissolving 100 parts of an acrylic acid ester based polymer (manufactured by Negami Industry Co., Ltd., 0.19 mol % of glycidyl acrylate) containing acrylonitrile-ethyl acrylate-butyl acrylate as a major component and having an epoxy value of 0.1, a glass transition point (Tg) of 15° C., and a weight-average molecular weight of 400,000 as the glycidyl-group-containing acrylic copolymer (a) and 12.5 parts of phenolic resin (manufactured by Meiwa Kasei Co., Ltd., “MEH7851”) as the phenolic resin (b) into methyl ethyl ketone, and further dispersing 40 parts of spherical silica (manufactured by Admatechs Co., Ltd., “SO-25R”) having an average particle size of 500 nm.

### Comparative Example 5

A die-bonding film was prepared in the same manner as in Example 1 except that an adhesive composition having a concentration of 23.6 wt % was prepared by dissolving 100 parts of an acrylic acid ester based polymer (manufactured by Negami Industry Co., Ltd., 0.19 mol % of glycidyl acrylate) containing acrylonitrile-ethyl acrylate-butyl acrylate as a major component and having an epoxy value of 0.18, a glass transition point (Tg) of 15° C., and a weight-average molecular weight of 800,000 as the glycidyl-group-containing acrylic copolymer (a) and 2.9 parts of phenolic resin (manufactured by Meiwa Kasei Co., Ltd., “MEH7851”) as the phenolic resin (b) into methyl ethyl ketone, and further dispersing 40 parts of spherical silica (manufactured by Admatechs Co., Ltd., “SO-25R”) having an average particle size of 500 nm.

### (Measuring Method for Weight-Average Molecular Weight)

With respect to the polymers and resins used respectively in the Examples and the Comparative Examples, the weight-average molecular weight was measured by gel permeation chromatography. The gel permeation chromatography was performed using four columns of TSK G2000H HR, G3000H HR, G4000H HR, and GMH-H HR (all manufactured by Tosoh Corporation) connected in series and using tetrahydrofuran as an eluant, under the conditions of a flow rate of 1 ml/min, a temperature of 40° C., a sample concentration of a 0.1% by weight tetrahydrofuran solution, and a sample injection amount of 500 μl, and using a differential refractometer as a detector.

### (Calculation of Epoxy Value)

The epoxy value was calculated in accordance with JIS K 7236. In detail, 4 g of the copolymer (a) was weighed into a conical flask having a volume of 100 ml, and 10 ml of chloroform was added to this and dissolved. Further, 30 ml of acetic acid, 5 ml of tetraethylammonium bromide, and 5 drops of a crystal violet indicator were added. While the mixture was being stirred with a magnetic stirrer, titration was carried out with 0.1 mol/L perchloric acid acetic acid normal solution. By a similar method, a blank test was carried out, and the epoxy value was calculated by the following formula.

epoxy value=[(V−B)×0.1×F]/W

W: g number of the weighed sample
B: ml number of the 0.1 mol/L perchloric acid acetic acid normal solution needed for the blank test
V: ml number of the 0.1 mol/L perchloric acid acetic acid normal solution needed for the titration of the sample
F: factor of the 0.1 mol/L perchloric acid acetic acid normal solution

### (Measurement of Storage Elastic Modulus)

The die-bonding film of each of the Examples and Comparative Examples was cut into short stripes having a length of 22.5 mm (measurement length)×width of 10 mm with a cutter knife, and the storage elastic modulus at −50 to 300° C. was measured by using a solid viscoelasticity measuring apparatus (RSAIII, manufactured by Rheometric Scientific Co., Ltd.). The measurement condition was set to be a frequency of 1 Hz and a temperature raising speed of 10° C./min. The values of the storage elastic modulus at 50° C. (before curing the die-bonding film), at 150° C. (with respect to the copolymer (a)), at 175° C. (after curing the die-bonding film), and at 260° C. (after curing the die-bonding film) are shown in the following Table 1. Here, the storage elastic modulus of the copolymer (a) was measured in a similar manner after fabricating a film sample by applying a solution containing the copolymer (a) onto a release treatment film, as a peeling-off liner, made of a polyethylene terephthalate film having a thickness of 50 μm and which was subjected to a silicone release treatment, followed by drying at 130° C. for 2 minutes. Also, the storage elastic modulus after curing was measured by a similar procedure after a curing treatment was carried out under a predetermined condition with a dryer.

### (Measurement of the Glass Transition Temperature (Tg))

For the glass transition point of each of the die-bonding films according to the examples and comparative examples, the storage elastic modulus was measured first in the same manner as in the above-described storage elastic modulus. Then, the loss elastic modulus was measured, and the glass transition temperature was obtained by calculating the value of tan δ (E″(loss elastic modulus)/E′ (storage elastic modulus)).

(Measurement of Shear Adhering Strength at 175° C. after Curing at 150° C. for One Hour)

With respect to the die-bonding films fabricated in the Examples and the Comparative Examples, the shear adhering strength to a semiconductor element was measured as follows.

First, each die-bonding film was subjected to a curing treatment for one hour in a dryer of 150° C. Thereafter, each die-bonding film was bonded to a semiconductor element (longitudinal side 5 mm×lateral side 5 mm×thickness 0.5 mm) at a bonding temperature of 50° C. with a laminator at a speed of 10 mm/sec and under a pressure of 0.15 MPa. Further, the die-bonding film was bonded to a semiconductor element (longitudinal side 10 mm×lateral side 10 mm×thickness 0.5 mm) at a bonding temperature of 50° C. with a laminator at a speed of 10 mm/sec and under a pressure of 0.15 MPa. Next, the shear adhering strength at a stage temperature of 175° C., a head height of 100 μm, and a speed of 0.5 mm/sec was respectively measured by using a bond tester (manufactured by Dagy Co., Ltd., dagy4000).

### (Measurement of Adhering Strength to a Wafer)

As a wafer, a silicon wafer was put on a heated plate, and a die-bonding film having a length of 150 mm, a width of 10 mm, and a thickness of 25 μm whose back surface had been reinforced with a pressure-sensitive adhesive tape (trade name: “BT315” manufactured by Nitto Denko Co., Ltd.) was bonded onto the silicon wafer by reciprocating a roller of 2 kg at 50° C. for one time. Thereafter, after being left to stand quietly on the heated plate of 50° C. for 2 minutes, the resultant was left to stand at an ordinary temperature (about 23° C.) for 20 minutes. Subsequently, the die-bonding film whose back surface had been reinforced was peeled off with use of a peeling-off tester (trade name: “AUTOGRAPH AGS-J, manufactured by Shimadzu Corporation”) under a condition with a temperature of 23° C., a peeling-off angle of 180°, and a pulling speed of 300 mm/min (peeling-off was made at the boundary between the die-bonding film and the silicon water). The maximum load upon peeling-off (maximum value of the load excluding the peak top at the initial stage of measurement) was measured, and this maximum load was determined as the adhering strength (N/10 mm width) between the die-bonding film and the silicon water. Evaluation was made by setting a case in which the adhering strength was 1 N/10 mm or more to be “◯” and a case in which the adhering strength was less than 1 N/10 mm to be “x”.

### (Wire Bonding Property)

Each of the die-bonding films obtained in the Examples and Comparative Examples was bonded to an aluminum-vapor-deposition semiconductor element (length of 5 mm×width of 5 mm×thickness of 0.5 mm) with a laminator at a temperature of 50° C. and at a speed of 10 mm/sec under a pressure of 0.15 MPa. This was further mounted on a BGA substrate under a condition with a temperature of 120° C., a pressure of 0.1 MPa, and a period of time of 1 s. Subsequently, wire bonding was carried out on 9 pieces of semiconductor elements under the following condition using a wire bonder (manufactured by Shinkawa Co., Ltd., trade name: “UTC-1000”). Evaluation was made by setting a case in which no defective sites were generated to be “◯” and a case in which one or more non-bonded sites or element cracks were generated to be “x”.

### (Wire Bonding Condition)

### Temp.: 175° C.

### Au-wire: 23 μm

### S-LEVEL: 50 μm

S-SPEED: 10 mm/s

### TIME: 15 ms

### US-POWER: 100

### FORCE: 20 gf

### S-FORCE: 15 gf

wire pitch: 100 μm

### (Confirmation of Sealing Resin Intrusion)

Each of the die-bonding films obtained in the Examples and Comparative Examples was bonded to a semiconductor element of 5 mm square at 40° C., and this was mounted on a BGA substrate under a condition with a temperature of 120° C., a pressure of 0.1 MPa, and a period of time of 1 s. This was further thermally treated at 150° C. for one hour with a dryer, and subsequently, a sealing step was carried out with use of a mold machine (manufactured by TOWA Press Co., Ltd., Manual Press Y-1) under a condition with a molding temperature of 175° C., a clamp pressure of 184 kN, a transfer pressure of 5 kN, a period of time of 120 seconds, and a sealing resin GE-100 (manufactured by Nitto Denko Co., Ltd.). Thereafter, the cross-section of the semiconductor element was observed at 9 sites by SEM, so as to confirm whether the sealing resin intruded or not between the die-bonding film and the substrate. Evaluation was made by setting a case in which the sealing resin did not intrude to be “◯” and a case in which the sealing resin intruded even at one site to be “x”.

(Air Bubble (Void) Disappearance Property after the Sealing Step)

Each of the die-bonding films obtained in the Examples and Comparative Examples was bonded to a semiconductor element of 5 mm square at 40° C., and this was mounted on a BGA substrate under a condition with a temperature of 120° C., a pressure of 0.1 MPa, and a period of time of 1 s. This was further thermally treated at 150° C. for one hour with a dryer, and thereafter a heat treatment at 120° C. for 10 hours or at 175° C. for 2 hours was carried out. Subsequently, a sealing step was carried out with use of a mold machine (manufactured by TOWA Press Co., Ltd., Manual Press Y-1) under a condition with a molding temperature of 175° C., a clamp pressure of 184 kN, a transfer pressure of 5 kN, a period of time of 120 seconds, and a sealing resin GE-100 (manufactured by Nitto Denko Co., Ltd.). The voids after the sealing step were observed with a supersonic video image apparatus (manufactured by Hitachi Finetech Co., Ltd., FS200II). The area occupied by the voids in the observed image was calculated by using a binarizing software (WinRoof ver. 5.6). Evaluation was made by setting a case in which the area occupied by the voids was less than 30% relative to the surface area of the die-bonding film to be “◯” and a case in which the area was 30% or more to be “x”.

### (Humidity Resistance Solder Reflow Test)

Each of the die-bonding films obtained in the Examples and Comparative Examples was bonded to a semiconductor element of 5 mm square at 40° C., and this was mounted on a BGA substrate under a condition with a temperature of 120° C., a pressure of 0.1 MPa, and a period of time of 1 s. After this was further thermally treated at 150° C. for one hour with a dryer, a heat treatment at 120° C. for 10 hours or at 175° C. for 2 hours was carried out. Subsequently, a sealing step was carried out with use of a mold machine (manufactured by TOWA Press Co., Ltd., Manual Press Y-1) under a condition with a molding temperature of 175° C., a clamp pressure of 184 kN, a transfer pressure of 5 kN, a period of time of 120 seconds, and a sealing resin GE-100 (manufactured by Nitto Denko Co., Ltd.). Thereafter, a humidity absorption operation was carried out under a condition with a temperature of 85° C., a humidity of 60% RH, and a period of time of 168 h, and the sample was passed through an IR reflow furnace of which temperature was set so that a temperature of 260° C. or higher would be maintained for 30 seconds. With respect to the 9 pieces of semiconductor elements, whether peeling-off was generated at the boundary between the die-bonding film and the substrate or not was confirmed with a supersonic microscope, and the ratio at which the peeling-off was generated was calculated.

The evaluation results are shown in Tables 1 and 2.

TABLE 1

| | | Example 1 | Example 2 | Example 3 | Example 4 | Example 5 | Example 6 |
|---|---|---|---|---|---|---|---|
| Value of ratio (x/y) of contents | | 5.7 | 8 | 15 | 24 | 5.7 | 24 |
| Epoxy value of copolymer (a) | | 0.18 | 0.22 | 0.42 | 0.62 | 0.62 | 0.18 |
| Glass transition point (Tg) [° C.] of | | 30 | 15 | 15 | 0 | 20 | 0 |
| copolymer (a) | | | | | | | |
| Storage elastic modulus [MPa] of | | 0.6 | 0.5 | 0.5 | 0.4 | 0.5 | 0.4 |
| copolymer (a) at 150° C. | | | | | | | |
| Weight-average molecular weight of | | 1,100,000 | 800,000 | 800,000 | 600,000 | 800,000 | 1,000,000 |
| copolymer (a) | | | | | | | |
| Low-molecular-weight epoxy resin | | None | None | None | None | None | None |
| component | | | | | | | |
| Before | Storage elastic modulus | 1 | 6 | 4 | 4 | 3 | 3 |
| curing | [MPa] at 50° C. | | | | | | |
| | Storage elastic modulus | 0.3 | 1 | 0.6 | 0.7 | 0.4 | 0.5 |
| | [MPa] at 175° C. | | | | | | |

| | | | | | | |
|---|---|---|---|---|---|---|
| Storage elastic modulus [MPa] at | 0.6 | 1.5 | 0.9 | 1.1 | 0.7 | 0.7 |
| 175° C. after curing at 150° C. × 1 h | | | | | | |
| Storage elastic modulus [MPa] at | 0.9 | 1.9 | 1.2 | 1.5 | 1 | 1 |
| 260° C. after curing at 175° C. × 1 h | | | | | | |
| Shear adhering strength [MPa] at | 0.35 | 0.36 | 0.5 | 1.2 | 1.5 | 0.3 |
| 175° C. after curing at 150° C. × 1 h | | | | | | |
| Adhering strength to wafer | ◯ | ◯ | ◯ | ◯ | ◯ | ◯ |
| Wire bonding property | ◯ | ◯ | ◯ | ◯ | ◯ | ◯ |
| Sealing resin intrusion | ◯ | ◯ | ◯ | ◯ | ◯ | ◯ |
| Void disappearance after sealing step | ◯ | ◯ | ◯ | ◯ | ◯ | ◯ |
| (120° C. × 10 h) | | | | | | |
| Void disappearance after sealing step | ◯ | ◯ | ◯ | ◯ | ◯ | ◯ |
| (175° C. × 1 h) | | | | | | |
| Humidity resistance solder reflow | 0 | 0 | 0 | 0 | 0 | 0 |
| test (120° C. × 10 h) | | | | | | |
| Humidity resistance solder reflow | 0 | 0 | 0 | 0 | 0 | 0 |
| test (175° C. × 1 h) | | | | | | |

TABLE 2

| | | Comparative | Comparative | Comparative | Comparative | Comparative |
|---|---|---|---|---|---|---|
| | | Example 1 | Example 2 | Example 3 | Example 4 | Example 5 |
| Value of ratio (x/y) of contents | | 5.7 | 15 | 4 | 8 | 35 |
| Epoxy value of copolymer (a) | | 0.18 | 0.42 | 0.18 | 0.18 | 0.18 |
| Glass transition point (Tg) [° C.] of copolymer | | 30 | 15 | 30 | 0 | 15 |
| (a) | | | | | | |
| Storage elastic modulus [MPa] of copolymer (a) | | 0.6 | 0.5 | 0.6 | 0.09 | 0.2 |
| at 150° C. | | | | | | |
| Weight-average molecular weight of copolymer | | 800,000 | 800,000 | 800,000 | 400,000 | 800,000 |
| (a) | | | | | | |
| Low-molecular-weight epoxy resin component | | Presented | Presented | None | None | None |
| Before | Storage elastic modulus [MPa] at 50° C. | 1 | 4 | 1.5 | 0.5 | 1.1 |
| curing | Storage elastic modulus [MPa] at 175° C. | 0.3 | 0.6 | 0.2 | 0.1 | 0.2 |

| | | | | | |
|---|---|---|---|---|---|
| Storage elastic modulus [MPa] at 175° C. after | 0.3 | 0.4 | 0.4 | 0.3 | 0.6 |
| curing at 150° C. × 1 h | | | | | |
| Storage elastic modulus [MPa] at 260° C. after | 0.9 | 1.2 | 0.4 | 0.3 | 0.7 |
| curing at 175° C. × 1 h | | | | | |
| Shear adhering strength [MPa] at 175° C. after | 0.2 | 0.25 | 0.25 | 0.2 | 0.3 |
| curing at 150° C. × 1 h | | | | | |
| Adhering strength to wafer | ◯ | ◯ | ◯ | ◯ | ◯ |
| Wire bonding property | ◯ | ◯ | ◯ | ◯ | ◯ |
| Sealing resin intrusion | X | X | X | X | ◯ |
| Void disappearance after sealing step (120° C. × | ◯ | ◯ | ◯ | ◯ | X |
| 10 h) | | | | | |
| Void disappearance after sealing step (175° C. × | ◯ | ◯ | ◯ | ◯ | X |
| 1 h) | | | | | |
| Humidity resistance solder reflow test (120° C. × | 0 | 0 | 100 | 100 | 100 |
| 10 h) | | | | | |
| Humidity resistance solder reflow test (175° C. × | 0 | 0 | 100 | 100 | 100 |
| 1 h) | | | | | |

### (Results)

From the above results, it is confirmed that, with the die-bonding film according to Examples, workability is good in all of the steps including the wire bonding step and the sealing step; even if a heat treatment is carried out at a high temperature for a long time after the die bond, air bubbles (voids) at the boundary between the die-bonding film and the adherend can be made to disappear after the step of sealing with a sealing resin which is a later step; a sufficient storage elastic modulus can be obtained after curing; and a high reliability can be ensured in a humidity resistance solder reflow test.

1. A die-bonding film, containing:
a glycidyl-group-containing acrylic copolymer (a) having a weight-average molecular weight of 500,000 or more; and
a phenolic resin (b),
wherein a weight ratio (x/y) of a content x of the glycidyl-group-containing acrylic copolymer (a) to a content y of the phenolic resin (b) is 5 or more and 30 or less, and the die-bonding film substantially does not contain an epoxy resin having a weight-average molecular weight of 5000 or less.

2. The die-bonding film according to claim 1, wherein, with respect to the glycidyl-group-containing acrylic copolymer (a),
an epoxy value thereof is 0.15 e.q./kg or more and 0.65 e.q./kg or less,
a glass transition point thereof is −15° C. or higher and 40° C. or lower, and
a storage elastic modulus thereof at 150° C. is 0.1 MPa or more.

3. The die-bonding film according to claim 1, wherein
a storage elastic modulus thereof at 50° C. before curing is 10 MPa or less,
a storage elastic modulus thereof at 175° C. is 0.1 MPa or more, and
a storage elastic modulus thereof at 175° C. after curing at 150° C. for one hour is 0.5 MPa or more.

4. The die-bonding film according to claim 1, wherein a storage elastic modulus thereof at 260° C. after curing at 175° C. for one hour is 0.5 MPa or more.

5. The die-bonding film according to claim 1, wherein a shear adhering strength between the die-bonding film and an adherend at 175° C. after bonding to the adherend and curing at 150° C. for one hour is 0.3 MPa or more.

6. The die-bonding film according to claim 1, containing 0.05 wt % or more of a dye.

7. A dicing die-bonding film, including:
a dicing tape; and
a die-bonding film according to claim 1 that is laminated on the dicing tape.

8. A method for manufacturing a semiconductor device, comprising:
bonding the die-bonding film of the dicing die-bonding film according to claim 7 and a back surface of a semiconductor wafer;
dicing the semiconductor wafer together with the dicing die-bonding film to form a chip-shaped semiconductor element;
picking up the semiconductor element together with the die-bonding film from the dicing die-bonding film;
die-bonding the semiconductor element on an adherend through the die-bonding film; and
performing wire bonding on the semiconductor element.

9. The die-bonding film according to claim 1, wherein the glycidyl-group-containing acrylic copolymer contains 1 to 20 mol % glycidyl-group-containing monomer.

10. The die-bonding film according to claim 1, wherein the phenolic resin (b) has a hydroxyl equivalent of 100 g/eq or more and 500 g/eq or less.

11. A semiconductor device, comprising the die-bonding film of claim 1 in cured form.
